(19) United States
(12) Patent Application Publication
(10) Pub. No.: US 2026/0030397 A1
(43) Pub. Date: Jan. 29, 2026

(54) APPARATUS AND METHOD FOR HOME ENERGY ASSESSMENT

(71) Applicant: SEEAIR, Inc., Cambridge, MA (US)

(72) Inventors: Piers Iain Ivo Octavian MACNAUGHTON, Cambridge, MA (US); Jacob Ian TAYLOR, North Easton, MA (US)

(21) Appl. No.: 19/275,264

(22) Filed: Jul. 21, 2025

Related U.S. Application Data
(60) Provisional application No. 63/676,814, filed on Jul. 29, 2024.

(51) Int. Cl. G06F 30/13; G06Q 10/04; G06Q 50/06

(52) U.S. Cl. CPC G06F 30/13; G06Q 10/043; G06Q 50/06

(57) ABSTRACT

A machine has a network interface circuit connected to a network with interconnectivity to a user machine and sensors. A processor is connected to the network interface circuit. A memory is connected to the processor. The memory stores instructions executed by the processor to prompt a user for video of a user home, prompt a user for survey data characterizing the user home, collect sensor data from the sensors, analyze the video of the user home, the survey data characterizing the user home, and the sensor data to produce a user home energy model with a three-dimensional (3D) model of the user home including labeled structural elements, construction materials, appliances, and energy-related features and a list of personalized recommendations for home improvement projects.

### CROSS REFERENCE TO RELATED APPLICATION

This application claims priority to U.S. Provisional Patent Application 63/676,814, filed Jul. 29, 2024, the contents of which are incorporated herein by reference.

### FIELD OF THE INVENTION

This invention relates generally to networked communications to collect home energy consumption information. More particularly, this invention is directed to supplying a home energy assessment from collected home energy consumption information.

### BACKGROUND OF THE INVENTION

Home energy assessments are crucial for identifying areas where energy efficiency can be improved. Traditional assessments often require professional auditors to visit the home, which can be costly and inconvenient for homeowners. Thus, there is a need for a more accessible and cost-effective solution that can provide accurate and actionable insights into a home's energy performance.

### SUMMARY

A machine has a network interface circuit connected to a network with interconnectivity to a user machine and sensors. A processor is connected to the network interface circuit. A memory is connected to the processor. The memory stores instructions executed by the processor to prompt a user for video of a user home, prompt a user for survey data characterizing the user home, collect sensor data from the sensors, analyze the video of the user home, the survey data characterizing the user home, and the sensor data to produce a user home energy model with a three-dimensional (3D) model of the user home including labeled structural elements, construction materials, appliances, and energy-related features and a list of personalized recommendations for home improvement projects.

### BRIEF DESCRIPTION OF THE DRAWINGS

The invention is more fully appreciated in connection with the following detailed description taken in conjunction with the accompanying drawings, in which:

FIG. 1 illustrates a system configured in accordance with an embodiment of the invention.

FIG. 2 illustrates processing operations associated with the energy assessment module.

FIG. 3 illustrates exemplary instructions for home assessment onboarding.

FIG. 4 illustrates an exemplary home energy assessment report generated in accordance with an embodiment of the invention.

Like reference numerals refer to corresponding parts throughout the several views of the drawings.

### DETAILED DESCRIPTION

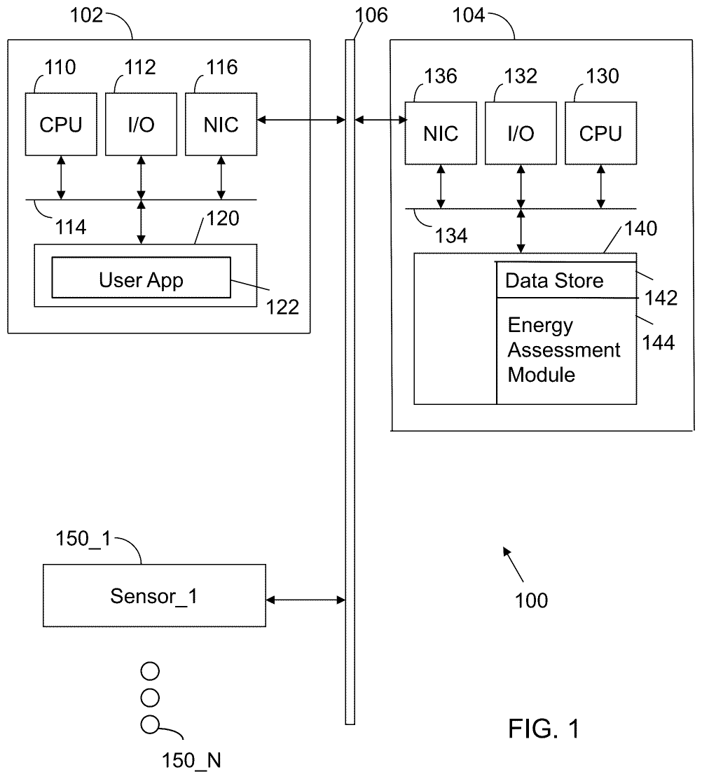

FIG. 1 illustrates a system 100 configured in accordance with an embodiment of the invention. The system 100 includes a user machine 102 in communication with a server 104 via a network 106, which may be any combination of wired and wireless networks. Sensors 150_1 through 150_N are also connected to the network 106. The sensors 150_1 through 150_N may be resident in a user home.

User machine 102 includes a processor 110 in communication with input/output devices 112 via a bus 114. The input/output devices 112 may include a keyboard, mouse, touch display and the like. A network interface circuit 116 is also connected to bus 114 to provide connectivity to network 106. A memory 120 is also connected to bus 114. The memory 120 stores instructions executed by processor 110. The instructions are a user application 122 to implement operations disclosed herein. The user machine 102 is typically a mobile device, such as a smartphone or tablet.

Server 104 includes a processor 130, input/output devices 132, a bus 134 and a network interface circuit 136 to provide connectivity to network 106. A memory 140 is also connected to bus 134. The memory 140 stores instructions executed by processor 130 to implement operations disclosed herein. The memory 140 includes a data store 142 to store home energy consumption information from user machine 102 and sensors 150_1 through 150_N. The memory also stores an energy assessment module 144 with instructions executed by processor 130 to implement operations disclosed herein.

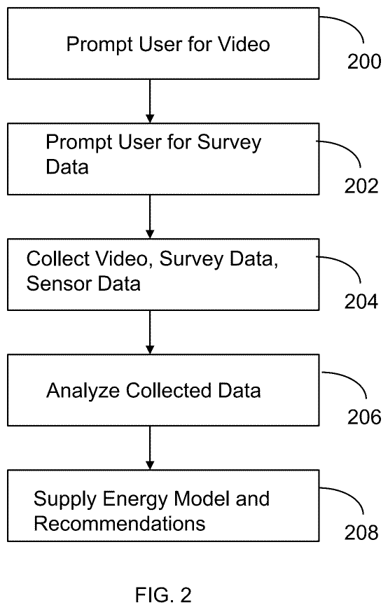

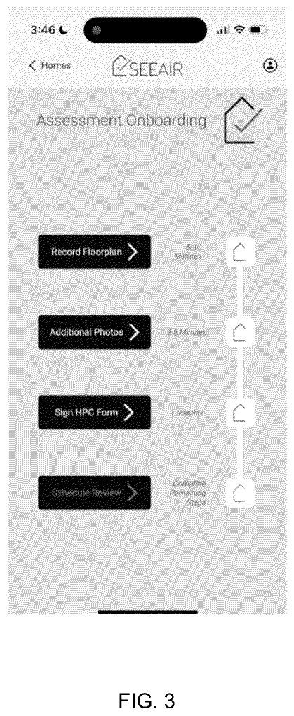

FIG. 2 illustrates operations performed by the energy assessment module 144. Initially, a user is prompted for video 200. FIG. 3 illustrates a user interface that may be supplied by the energy assessment module 144 for display on the user machine 102. The user interface includes detailed instructions on how to initiate a home energy assessment.

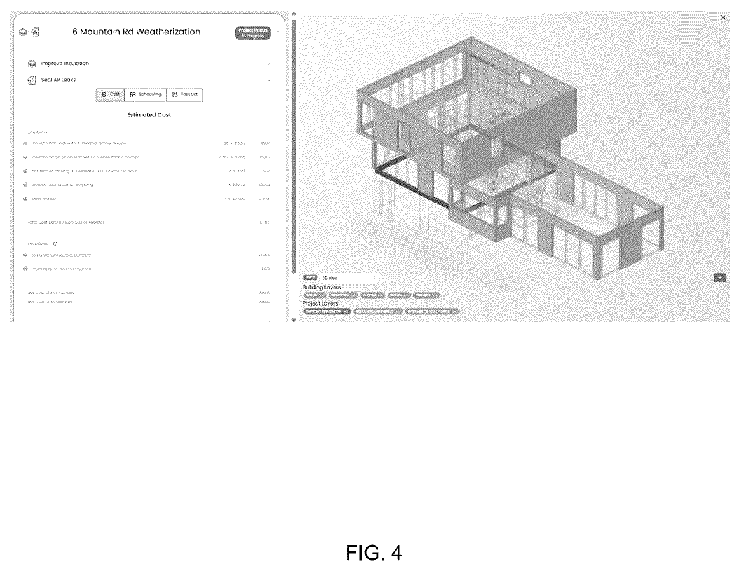

The user is then prompted for survey data 202, examples of which are provided below. Sensors 150_1 through 150_N have a network connection to server 104, which receives sensor measurements via the network 106. The energy assessment module 144 collects video (including audio), survey data and sensor data 204. The collected data is analyzed 206. The energy assessment module 144 then supplies an energy model and recommendations. FIG. 4 provides an example of such an energy model that may be supplied to user machine 102 via network 106.

As previously indicated, the energy assessment module 144 collects video footage of the interior of a home. The energy assessment module 144 leverages advanced computer vision algorithms to process this video data, generating a detailed 3D model of the home's current structural and material properties. The energy assessment module 144 detects and maps structural elements, building materials, windows, doors, and other critical features to create an accurate 3D model of the home.

The energy assessment module 144 supplies prompts with surveys designed to collect information about the home building systems, appliances and other relevant factors. Homeowners provide this information through a user-friendly mobile application. These surveys gather information on current energy usage patterns (e.g., electricity, gas consumption), insulation levels and types, heating, ventilation, and air conditioning (HVAC) systems, window and door types and conditions, and recent home improvement projects and planned upgrades

Sensors 150_1 through 150_N are deployed within the home to gather data on parameters such as temperature, humidity, and pollutants. This data is used to assess the home's indoor air quality and potential solutions. In one embodiment, carbon dioxide sensors, volatile organic compound sensor and particulate matter sensors (PM2.5 and PM10) are used.

The video processing performed by the energy assessment module 144 forms a three-dimensional (3D) representation of the home scaled to proper dimensions. This includes size, number and location of windows to produce takeoffs for high-performing replacement windows. Computer vision algorithms label existing building construction materials such as insulation using trained datasets captured at prior homes and geolocates those onto the 3D model along with their square footage. Building materials such as windows, doors and siding, along with an assessment of their current condition are specified. Insulation materials such as fiberglass, polyisocyanurate, XPS, cellulose are identified and matched with appropriate R-values. An R-value is a measure of how well a material resists heat flow. The higher the R-value the better the insulation. The model also downgrades R-values based on the visual assessment of the quality of the installation and any other visible degradation. Because of the 3D model and increased computational abilities, downgrading of R-values is done by applying a weighted average across the full scope of insulation, rather than applying a single rating of the material as is typically done by a trained assessor.

Computer vision algorithms label appliance make and model (e.g. stove, water heater, furnace) and pull performance data such as efficiency metrics from a database populated from manufacturer specifications. Computer vision algorithms detect potential safety issues that require immediate notification to the homeowner and remediation prior to subsequent project work. The presence of knob and tube wiring that may pose a fire hazard is identified. The presence and quantity of asbestos or vermiculite as insulation are identified. The presence of mold or water damage is identified. The lack of smoke and/or carbon monoxide detectors is specified.

Based on the characterizations of the building structure, material composition and building system/appliance information, a high-fidelity energy model is produced and calibrated against the customer's utility information according to Building Performance Institute standards (e.g., BPI-2400).

Based on the energy model, the system generates a list of customized recommendations for home improvement projects aimed at enhancing energy efficiency. These recommendations may include: insulation upgrades (e.g., attic, walls, floors), air sealing to reduce drafts and improve thermal envelope integrity, installation of energy-efficient windows and doors, HVAC system upgrades or maintenance, implementation of heat pumps for heating and cooling, recommendations for improving indoor air quality (e.g., ventilation improvements). The recommendations are iteratively modified in the energy model to produce energy saving estimations with greater accuracy than traditional energy modeling approaches.

The system compiles the assessment results and recommendations into a comprehensive energy assessment, which is delivered to the homeowner through mobile and web applications. The system creates a building information model by overlaying recommendations onto the 3D representation of the home. For example, areas that lack sufficient insulation will have a layer added to the model with the appropriate insulation to be installed following the assessment. The precise square footage of material is produced from the 3D model and compared against unit prices lists. Recommendations may have quotes for the project automatically generated based on the identified requirements and scope of each. The system may also offer follow-up services, such as connecting homeowners with qualified contractors, tracking the progress of improvement projects, and conducting post-upgrade assessments to measure improvements in energy efficiency.

In one embodiment, the 3D model includes scaling and spatial measurements of walls, windows, and doors to determine insulation areas and material requirements. In another embodiment, the energy assessment module 144 uses computer vision techniques to detect and classify insulation materials and assign or adjust R-values based on installation quality or degradation. The energy assessment module 144 uses audio data to determine the presence of insulation in wall cavities and other inaccessible areas. In one embodiment, the audio data is analyzed against a database of acoustic signatures through machine learning to classify the type, quantity and performance of insulation materials. The energy assessment module 144 may access machines connected to network 106 to perform this operation.

The energy assessment module 144 uses computer vision techniques to identify appliances by make and model. Efficiency ratings are retrieved from a network connected performance specification database.

In one embodiment, the home energy model specifies safety hazards including: knob and tube wiring, asbestos or vermiculite insulation, mold or water damage, and absence of smoke or carbon monoxide detectors. In one embodiment, the energy model is calibrated against utility usage data according to Building Performance Institute standards. In one embodiment, the energy assessment module generates a building information model (BIM) that overlays recommended upgrades onto the 3D home model. In one embodiment, the personalized recommendations include predicted energy savings estimates produced by iterative modification of the energy model.

Those skilled in the art will recognize numerous advantages associated with the disclosed system. Homeowners can perform the assessment at their convenience using their smartphones, without the need for professional auditors. The system reduces the costs associated with traditional energy audits, making energy assessments more affordable. The combination of video capture, user surveys, and air quality sensors provides a comprehensive and accurate assessment of the home's energy performance. The system generates personalized recommendations tailored to the specific needs and conditions of each home. By assessing and addressing air quality and thermal issues, the system contributes to healthier living environments.

An embodiment of the present invention relates to a computer storage product with a computer readable storage medium having computer code thereon for performing various computer-implemented operations. The media and computer code may be those specially designed and constructed for the purposes of the present invention, or they may be of the kind well known and available to those having skill in the computer software arts. Examples of computer-readable media include but are not limited to: magnetic media, optical media, magneto-optical media, and hardware devices that are specially configured to store and execute program code, such as application-specific integrated circuits (“ASICs”), programmable logic devices (“PLDs”) and ROM and RAM devices. Examples of computer code include machine code, such as produced by a compiler, and files containing higher-level code that are executed by a computer using an interpreter. For example, an embodiment of the invention may be implemented using an object-oriented programming language and development tools. Another embodiment of the invention may be implemented in hardwired circuitry in place of, or in combination with, machine-executable software instructions. Another embodiment may use prompt engineering of large language models.

The foregoing description, for purposes of explanation, used specific nomenclature to provide a thorough understanding of the invention. However, it will be apparent to one skilled in the art that specific details are not required to practice the invention. Thus, the foregoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described to best explain the principles of the invention and its practical applications, they thereby enable others skilled in the art to best utilize the invention and various embodiments with various modifications as are suited to the particular use contemplated. It is intended that the following claims and their equivalents define the scope of the invention.

1. A machine, comprising:
a network interface circuit connected to a network with interconnectivity to a user machine and sensors;
a processor connected to the network interface circuit;
a memory connected to the processor, the memory storing instructions executed by the processor to:
prompt a user for video of a user home,
prompt a user for survey data characterizing the user home,
collect sensor data from the sensors,
analyze the video of the user home, the survey data characterizing the user home, and the sensor data, and
produce a user home energy model with a three-dimensional (3D) model of the user home including labeled structural elements, construction materials, appliances, and energy-related features and a list of personalized recommendations for home improvement projects.

2. The machine of claim 1, wherein the 3D model includes scaling and spatial measurements of walls, windows, and doors to determine insulation areas and material requirements.

3. The machine of claim 1, wherein computer vision techniques detect and classify insulation materials and assign or adjust R-values based on installation quality or degradation.

4. The machine of claim 1, wherein audio data is analyzed to determine the presence of insulation in wall cavities and other inaccessible areas.

5. The machine of claim 1, wherein computer vision techniques identify appliances by make and model and retrieve efficiency ratings from a network connected performance specification database.

6. The machine of claim 1, wherein the home energy model specifies safety hazards including:
knob and tube wiring, asbestos or vermiculite insulation, mold or water damage, and absence of smoke or carbon monoxide detectors.

7. The machine of claim 1 wherein the sensor data includes at least one of: temperature, humidity, carbon dioxide (CO₂), volatile organic compounds (VOCs), and particulate matter (PM2.5, PM10).

8. The machine of claim 1, wherein audio data is analyzed against a database of acoustic signatures through machine learning to classify the type, quantity and performance of insulation materials.

9. The machine of claim 1, wherein the energy model is calibrated against utility usage data according to Building Performance Institute standards.

10. The machine of claim 1, further comprising a module for generating a building information model (BIM) that overlays recommended upgrades onto the 3D home model.

11. The machine of claim 1, wherein the personalized recommendations include predicted energy savings estimates produced by iterative modification of the energy model.
